(19) United States
(12) Patent Application Publication
(10) Pub. No.: US 2011/0006324 A1
(43) Pub. Date: Jan. 13, 2011

(54) Lighting Device

(76) Inventor: Ralph Wirth, Mintraching-Auhof (DE)

Correspondence Address: SLATER & MATSIL, L.L.P., 17950 PRESTON RD, SUITE 1000, DALLAS, TX, 75252-5793, US

(21) Appl. No.: 12/744,465

(22) PCT Filed: Nov. 26, 2008
(86) PCT No.: PCT/DE08/01959

§ 371 Date: Aug. 20, 2010

(30) Foreign Application Priority Data
Nov. 30, 2007 (DE) 10 2007 057 671.6

(51) Int. Cl. H01L 33/10

(52) U.S. Cl. 257/98; 257/E33.072

(57) ABSTRACT

The present invention provides a lighting device with a chip housing with at least one recess, which is defined by a reflective internal surface. The lighting device also includes at least one radiation-emitting semiconductor chip with a chip surface, which is arranged in the recess. A chip-remote angular filter element is integrated into the chip housing and is arranged downstream of the semiconductor chip in a preferred direction. The reflective internal surface is at least ten times as large as the chip surface.

This patent application is a national phase filing under section 371 of PCT/DE2008/001959, filed Nov. 26, 2008, which claims the priority of German patent application 10 2007 057 671.6, filed Nov. 30, 2007, each of which is incorporated herein by reference in its entirety.

### TECHNICAL FIELD

The present invention relates to a lighting device, which is suitable in particular for general lighting.

### BACKGROUND

In the case of general lighting, a laterally homogeneous distribution of the radiant intensity on the radiation exit side of the lighting device is often desired. In particular, the radiant intensity at each exit face should be distributed as homogeneously as possible on the radiation exit side.

As a result of the often limited spatial extent of the radiation source, which may be composed of one or more radiation-emitting semiconductor chips, achieving homogeneous radiant intensity distribution in the case of a large area radiation exit face, whose area is greater than the area covered laterally by the radiation source is often difficult. In particular, regions on the radiation exit side with a radiant intensity higher than the adjoining regions may form “hot spots”, which stem from the regions illuminated directly with the radiation source. This is generally undesirable in the case of applications which require uniform radiant intensity on the radiation exit side.

Furthermore, with general lighting a limited angle of radiation may be desired, so as to be able to illuminate areas in a sharply delimited manner. Hitherto, beam shaping has primarily been effected by optical elements such as lenses, which have to be precisely adjusted relative to the radiation source and have a decisive influence on the structural height of the lighting device.

### SUMMARY

In one aspect, a lighting device is provided with compact structure, which simplifies the provision of homogeneous radiant intensity distribution on the radiation exit side of the lighting device in a lateral direction.

According to one advantageous embodiment of the invention the lighting device comprises a chip housing with at least one recess, which is defined by a reflective internal surface and at least one radiation-emitting semiconductor chip with a chip surface, the chip surface being arranged in the recess, and a chip-remote angular filter element, which is integrated into the chip housing and is arranged downstream of the semiconductor chip in a preferred direction, the reflective internal surface being at least ten times as large as the chip surface.

The chip surface is composed of the sub-surfaces of the semiconductor chip on which radiation may impinge. In particular, these are the side surfaces of the semiconductor chip and a top surface of the semiconductor chip facing the angular filter element. If the semiconductor chip is planar in form, i.e., if the length and the width are significantly greater than the height of the semiconductor chip, the chip surface is equated with the top surface. In the case of a plurality of semiconductor chips, the total chip surface is composed of all the chip surfaces of the individual semiconductor chips combined.

According to a further advantageous embodiment of the invention, the reflective internal surface is a hundred times greater than the chip surface.

With a surface area ratio between the reflective internal surface and the chip surface which is greater than 10:1, in particular greater than 100:1, the probability of light beams, which are reflected back into the chip housing by means of the angular filter element, being absorbed by the semiconductor chip is advantageously reduced. This is advantageous insofar as the reflectivity of the semiconductor chip generally amounts to only between 20% and 80%, while a greater reflectivity may be achieved by the reflective internal surface. The reflectivity of the reflective internal surface preferably amounts to 90% or more, preferably 95% or more, particularly preferably 98% or more. By means of such a reflectivity it is possible to advantageously increase the efficiency of the lighting device, since only a small radiation fraction is lost in the chip housing through absorption.

As has already been described above, regions may occur on the radiation exit side with a higher radiant intensity than the adjoining regions or regions may form, in the case of polychromatic radiation, which have a markedly different spectral composition compared with adjoining regions.

To counteract this and achieve homogeneous radiant intensity distribution and/or color distribution on the radiation exit side, use is made of the angular filter element.

According to one advantageous embodiment the radiation emitted by the semiconductor chip, which impinges on the angular filter element, may be more strongly reflected within a first incidence angle range than within a second incidence angle range, wherein the first incidence angle range has smaller angles of incidence than the second incidence angle range. This embodiment is suitable, in particular, in the case of indirect, large-area lighting.

According to an alternative embodiment the radiation emitted by the semiconductor chip, which impinges on the angular filter element, is reflected more strongly within the second incidence angle range than within the first incidence angle range. This embodiment is suitable, in particular, in the case of spot lighting.

In addition, the angular filter element may either reflect the radiation within the first incidence angle range more strongly than the radiation within the second incidence angle range or vice versa, as a function of the radiation properties of the radiation source and the desired radiation pattern.

The light beams reflected at the angular filter element are reflected back into the chip housing, where they ideally circulate until they impinge on the angular filter element with a non-critical angle of incidence and may couple out of the lighting device.

Furthermore, the angle of radiation of the overall radiation emitted by the lighting device may preferably be reduced by means of the angular filter element. In this respect, the angular filter element assumes the function of a beam-shaping optical element. However, the angular filter element in particular has a smaller depth than a conventional optical element, such that the structural depth of the lighting device is advantageously reduced.

In a preferred embodiment of the lighting device, the angular filter element comprises structure elements. The structure elements may be of conical, pyramidal or prismatic construction or resemble inverse CPCs. The structure elements may be of identical size and identical shape and be regularly arranged. However, it is also possible for the structure elements to be differently sized, differently shaped and arranged at irregular intervals. The structure elements may extend by a few micrometers or up to a few centimeters. In an extreme case, the angular filter element may comprise just one structure element, which extends over the entire radiation exit plane of the lighting device.

According to a further embodiment the angular filter element is a dielectric filter. The dielectric filter comprises at least two dielectric layers with different refractive indexes.

Silicon-containing materials are suitable for the dielectric filter. For example, a first layer may contain a silicon oxide and a second layer a silicon nitride. Titanium-containing materials may moreover also be used for the dielectric filter. For example, a first layer may contain a silicon oxide and a second layer a titanium oxide. In particular, the layers comprise a layer thickness of λ₀/4n, λ₀ being the vacuum wavelength of the radiation to be reflected and n being the refractive index in the respective dielectric layer.

The reflective internal surface is described in greater detail below. The reflective internal surface may be formed, for example, by applying a reflector layer to the internal surface of the chip housing, for example, by vapor depositing a metallic layer, for example, an aluminum layer, or applying a metal foil to the chip housing. In this case the chip housing does not have to be made from a reflective material. It may, for example, contain a plastics material and/or a ceramic material.

However, it is also feasible for the chip housing to be made from a reflective material. For example, the chip housing may be made from a single metal part, for example, from a deep-drawn aluminum part. In this case no reflector layer has to be provided on the internal surface of the chip housing, since the reflectivity of the chip housing is already sufficient.

In a preferred further development, the internal surface is smooth, i.e., it only has roughness features which are small relative to the wavelength λ. In this way, specular reflection may take place, i.e., the angle of incidence of an incident light beam and the reflection angle are of equal size, relative to the normal at the point of incidence.

It is however also possible for the internal surface to comprise unevennesses which are large relative to the wavelength λ. In particular, the internal surface is roughened by means of the unevennesses in such a way that smooth sub-surfaces form which extend obliquely relative to one another and act as mirror surfaces. This configuration is advantageous, in particular, in the case of polychromatic radiation, because in this way better mixing of different color components may be achieved on reflection at the internal surface.

The reflective internal surface may comprise at least one side surface. The side surface is here inclined relative to a main plane, in which the angular filter element extends. Preferably, the side surface directly adjoins the angular filter element.

According to one advantageous variant of the lighting device, at least one side surface is curved concavely. Through curvature of the side surface, reflection in the chip housing may be advantageously influenced.

In addition, the internal surface may comprise a bottom surface, which is arranged parallel to the main plane of the angular filter element and thus extends at an angle to the side surface. In particular, the lighting device comprises a planar bottom surface and a plurality of planar side surfaces, which adjoin the bottom surface.

It is advantageous for both the side surface and the bottom surface to have a reflectivity of 90% or greater, preferably of 95% or greater, particularly preferably of 98% or greater.

According to a preferred configuration, the angular filter element forms a cover for the chip housing. The angular filter element may rest on the chip housing or be arranged custom-fit in the recess. The angular filter element may then protect the semiconductor chip from external influences. The angular filter element is integrated into the chip housing both by arrangement of the angular filter element on the chip housing and by arrangement in the recess.

A further possible option for incorporating the angular filter element in the chip housing consists in making the side wall of the chip housing from the same material as the angular filter element. In this case the side wall and the angular filter element may be produced as a one-piece, self-supporting cover, which is put over the semiconductor chip. Preferably the cover is arranged on a base plate on which the semiconductor chip is also mounted. The cover may contain a plastics material, for example, and be produced by injection molding.

In an advantageous variant the lighting device may comprise a plurality of semiconductor chips, which are arranged next to one another in the chip housing and emit radiation of the same wavelength. To produce polychromatic radiation a conversion element may be arranged downstream of the semiconductor chips in the preferred direction, which conversion element allows a first radiation fraction of the radiation generated by the semiconductor chip to pass through unchanged, such that the unchanged radiation fraction has a relatively short wavelength, and which converts a second radiation fraction, such that the converted radiation fraction has a relatively long wavelength. The conversion element may be arranged close to the chip, such that the conversion element directly adjoins the semiconductor chip. Alternatively, the conversion element may be arranged remote from the chip, such that the conversion element does not directly adjoin the semiconductor chip.

In a further advantageous variant the lighting device comprises a plurality of semiconductor chips, which are arranged next to one another in the chip housing and emit radiation of different wavelengths. In particular, the lighting device comprises in regular succession a red-emitting semiconductor chip, a green-emitting semiconductor chip and a blue-emitting semiconductor chip.

### BRIEF DESCRIPTION OF THE DRAWINGS

Further features, advantages and further developments of the invention are revealed by the exemplary embodiments explained below in conjunction with FIGS. 1 to 7, in which:

FIG. 1 is a schematic cross-sectional view of a first exemplary embodiment of a lighting device according to the invention;

FIG. 2 is a schematic cross-sectional view of a second exemplary embodiment of a lighting device according to the invention;

FIG. 3 is a schematic cross-sectional view of a third exemplary embodiment of a lighting device according to the invention;

FIG. 4A shows a schematic plan view and FIG. 4B shows a schematic cross-sectional view of a fourth exemplary embodiment of a lighting device according to the invention;

FIG. 5 shows a chart illustrating the reflectivity-dependent extraction efficiency of a lighting device according to the invention;

FIG. 6 illustrates the radiant intensity distribution of a Lambertian emitter; and

FIG. 7 illustrates the radiant intensity distribution of a lighting device according to the invention.

### DETAILED DESCRIPTION OF ILLUSTRATIVE EMBODIMENTS

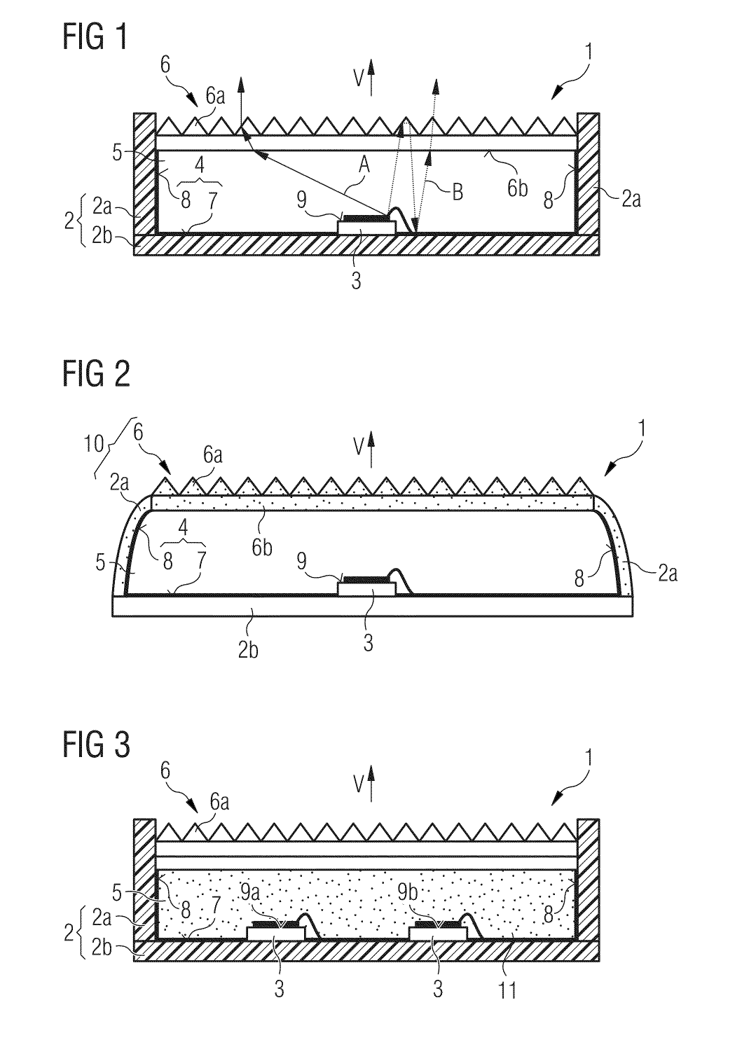

The lighting device 1 shown in FIG. 1 includes a chip housing 2, in which a radiation-emitting semiconductor chip 3 is arranged. A chip-remote angular filter element 6 is integrated into the chip housing 2, which filter element is arranged downstream of the radiation-emitting semiconductor chip 3 in a preferred direction V.

The preferred direction V is here the direction in which a large part of the radiation output by the lighting device 1 is emitted.

The radiation-emitting semiconductor chip 3 is arranged in a recess 5 in the chip housing 2. The recess 5 is defined by an internal surface 4, which comprises a bottom surface 7 and a plurality of side surfaces 8. The side surfaces 8 and the bottom surface 7 are planar, the side surfaces 8 extending perpendicularly to the bottom surface 7. Since the length of the chip housing 2 is substantially greater than the height, the chip housing 2 is planar in form.

The chip housing 2 comprises a base plate 2b with the bottom surface 7 and side walls 2a with the side surfaces 8. The base plate 2b may, for example, contain a ceramic material, in particular a material with high thermal conductivity, in order to cool the radiation-emitting semiconductor chip 3 sufficiently when in operation. In addition, a plastics material is suitable for the side walls 2a.

The inside of the chip housing 2 may be mirrored, for example, such that the internal surface 4 is reflective. The reflectivity of the reflective internal surface 4 preferably amounts to 90% or more, preferably 95% or more, particularly preferably 98% or more. By means of such a reflectivity it is advantageously possible to increase the efficiency of the lighting device 1, since only a small radiation fraction is lost in the chip housing 2 through absorption.

The internal surface 4 and a chip surface 9 of the semiconductor chip 3, the chip surface 9 in this case being a top surface of the semiconductor chip 3 facing the angular filter element 6, are dimensioned relative to one another in such a manner that reflections take place in the chip housing 2 mainly at the internal surface 4. Preferably, the internal surface 4 is at least ten times as large as the chip surface 9. The internal surface 4 is particularly preferably a hundred times larger than the chip surface 9. For example, the internal surface 4 may be 1 cm² in size, while the chip surface 9 is 1 mm² in size.

The angular filter element 6 comprises a plurality of pyramidal structure elements 6a with inclined side faces. In the exemplary embodiment the angle between the inclined side faces is the same for all the structure elements 6a. For the purposes of the invention angles between 70° and 110° are preferred.

It is also feasible for different angles to be used between the inclined side faces. This allows the suppression of outlines of the structure elements 6a on an illuminated surface. In addition, pattern formation may be prevented in that non-rotationally symmetrical structure elements 6a are turned relative to one another and/or are differently shaped and/or are arranged irregularly.

In the exemplary embodiment of FIG. 1 the structure elements 6a are arranged on a surface of the angular filter element 6 remote from the semiconductor chip 3, the structure elements 6a tapering in the preferred direction V.

A surface 6b of the angular filter element 6 facing the semiconductor chip 3 is of planar configuration. The surface 6b is located in a main plane of the angular filter element 6. The main plane is arranged parallel to a radiation exit plane of the lighting device 1 and perpendicular to the preferred direction V.

The angular filter element 6 may, for example, be an injection molding or made from a support plate, onto which a coating layer is applied, from which the structure elements 6a are formed.

Part of the radiation emitted by the semiconductor chip 3 may initially impinge on the angular filter element 6. A first radiation fraction is transmitted there by the angular filter element 6, while a second radiation fraction is reflected back into the chip housing 2.

In the present exemplary embodiment, by means of the angular filter element 6, the light beams with n angle of incidence which lies within the second incidence angle range, i.e., light beams with a relatively large angle of incidence, may be transmitted by the angular filter element 6. This is illustrated in FIG. 1 by light beam A.

The light beam A impinges on the surface 6b of the angular filter element 6 and is “refracted towards” the normal at the point of incidence, the angle of incidence being larger than the angle of emergence. The light beam A passes through the angular filter element 6 and impinges on the inclined side face of the structure element 6a at a non-critical angle, such that the light beam A may couple out of the angular filter element 6. On exit from the angular filter element 6 the light beam A is “refracted away” from the normal at the point of incidence and consequently deflected into the preferred direction V.

Light beams with an angle of incidence which lies within the first incidence angle range, i.e., light beams with a relatively small angle of incidence, may in the present exemplary embodiment be reflected by the angular filter element 6. This is illustrated in FIG. 1 by light beam B.

The light beam B impinges substantially parallel to the preferred direction V on the surface 6b of the angular filter element 6 and is therefore barely deflected. At one of the inclined side faces of the structure element 6a the light beam B is totally reflected and impinges on the opposing side face of the structure element 6a. Here the light beam B is again totally reflected. After reflection the light beam B re-enters the chip housing 2 and is reflected there, in particular at the internal surface 4, until the light beam B impinges on the angular filter element 6 at a non-critical angle and may couple out. The light beam B then has a direction which deviates only slightly from the preferred direction V.

The radiation emitted by the lighting device 1 may be advantageously mixed by means of the angular filter element 6, i.e., light beams of the first and second angle ranges are equally present in any desired region of a radiation exit plane of the lighting device 1. In this case, the radiation exit plane extends perpendicular to the preferred direction V.

In addition, beam shaping of the radiation emitted by the lighting device 1 may be brought about by means of the present angular filter element 6. In particular, the angle of radiation is restricted by means of the angular filter element 6.

In the exemplary embodiment of FIG. 1 the radiation-emitting semiconductor chip 3 preferably contains a nitride compound semiconductor and is a thin film semiconductor chip. When producing the thin film semiconductor chip 3 a semiconductor layer sequence comprising a radiation-emitting active layer is initially grown epitaxially on a growth substrate. Then a support is applied to an opposite surface of the semiconductor layer sequence from the growth substrate and the growth substrate is subsequently detached. Since the growth substrates used in particular for nitride compound semiconductors, for example, SiC, sapphire or GaN, are comparatively expensive, this method offers, in particular, the advantage that the growth substrate may be reused.

The basic principle of a thin film LED is described, for example, in I. Schnitzer et al., Appl. Phys. Lett. 63 (16), 18 October 1993, 21740-2176, the disclosure content of which is hereby included in this respect by reference.

The thin film semiconductor chip is a Lambertian emitter with advantageous outcoupling efficiency.

The angular filter element 6 is inserted custom-fit into the chip housing 2 and covers the recess 5 in the chip housing 2. Thus, the radiation-emitting semiconductor chip 3 may be protected from external influences such as moisture, dust or other foreign bodies.

A cavity formed between the radiation-emitting semiconductor chip 3 and the angular filter element 6 is filled with air in this exemplary embodiment. In this way, an advantageously large refractive index jump may be achieved at the junction between the cavity and the angular filter element 6.

The lighting device 1 shown in FIG. 2 comprises a similar structure to the lighting device of FIG. 1. However, in the exemplary embodiment of FIG. 2 the side walls 2a and the angular filter element 6 are of one-piece construction. In particular, the self-supporting cover 10 formed in this way is an injection molding. The cover 10 is drawn over the semiconductor chip 3 and arranged on the base plate 2b.

The side walls 2a may be provided with a reflector layer, before the cover 10 is arranged on the base plate 2b, such that as a result the side surface 8 is reflective.

To generate polychromatic radiation, a conversion element may be arranged downstream of both the semiconductor chip 3 shown in FIG. 1 and the semiconductor chip 3 shown in FIG. 2. This may adjoin the semiconductor chip 3 directly or be arranged at a distance from the semiconductor chip 3. In addition, the lighting devices shown in FIGS. 1 and 2 may also comprise a plurality of semiconductor chips, which generate radiation of the same wavelength and downstream of which a conversion element is optionally arranged.

FIG. 3 shows a lighting device 1 comprising a plurality of radiation-emitting semiconductor chips 3. The radiation-emitting semiconductor chips 3 are arranged next to one another on the base plate 2b.

In this exemplary embodiment the overall chip surface is composed of all the individual chip surfaces 9a and 9b combined. As regards to the surface area ratio, the reflective internal surface 4 is at least ten times as large as, preferably a hundred times larger than the individual chip surfaces 9a and 9b combined.

The radiation-emitting semiconductor chips 3 generate radiation with various wavelengths. Preferably the lighting device 1 comprises at least one semiconductor chip which generates red light, one which generates blue light and one which generates green light, such that overall white light is emitted by the lighting device 1.

By means of the angular filter element 6, the differently colored radiation may advantageously be mixed in the radiation exit plane, such that no differently colored light spots arise.

The recess 5 is partially filled with a filling composition 11. In this way radiation outcoupling from the semiconductor chip 3 may be improved. In addition, an advantageously large refractive index jump may be achieved at the junction with the angular filter element 6 by means of the air gap between the filling composition 11 and the angular filter element 6.

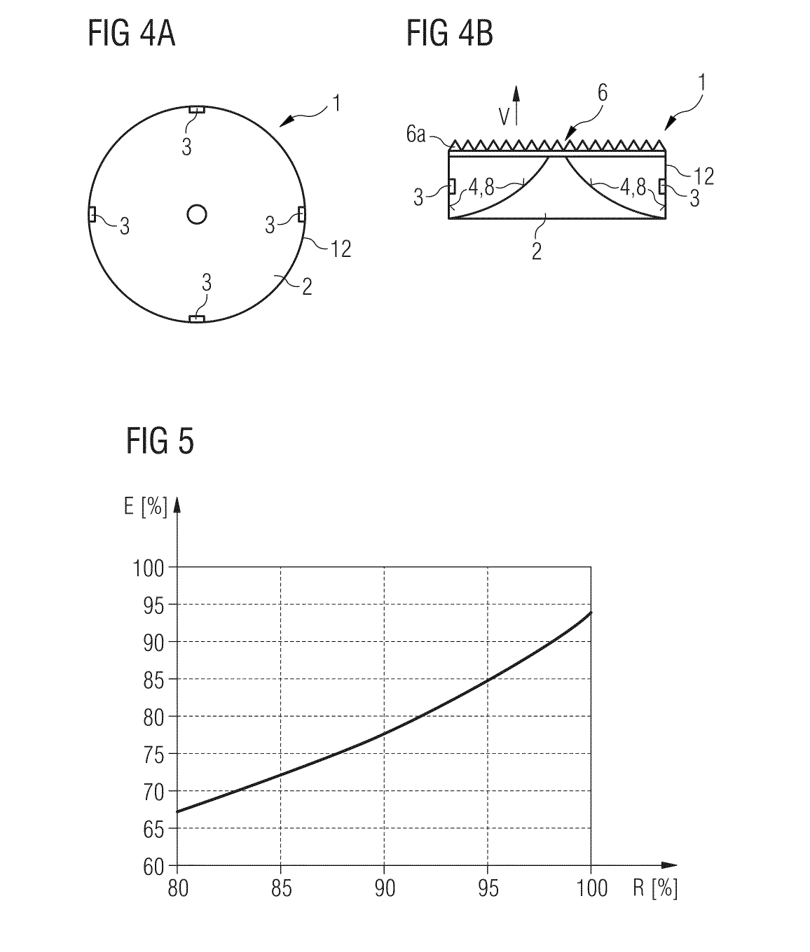

The lighting device 1 shown in FIGS. 4A and 4B comprises a chip housing 2 with a round outline and a plurality of radiation-emitting semiconductor chips 3, which are arranged on internal side surfaces 8 of the chip housing 2.

The chip housing 2 includes a plurality of recesses 5, which are arranged along an outer wall 12 of the lighting device 1. A surface illuminated by such a lighting device 1 constitutes a luminous ring.

As is clear in the cross-sectional view of FIG. 4B, the side surfaces 8 opposite the semiconductor chips 3 are concavely curved. In this way the radiation generated by the semiconductor chips 3 may be advantageously deflected into the preferred direction V.

Although the recesses 5 are separated from one another by the chip housing 2, mixing of the radiation generated by the individual semiconductor chips 3 may nevertheless be achieved in the radiation exit plane by means of the angular filter element 6.

In the chart in FIG. 5 the extraction efficiency E of a lighting device according to the invention is plotted against the reflectivity R of the reflective internal surface.

As is clear from the chart, an increase in the reflectivity R may bring about an increase in the extraction efficiency E of the lighting device. With a reflectivity R of 95%, for example, 85% of the radiation generated by the semiconductor chip or the semiconductor chips may be coupled out of the lighting device.

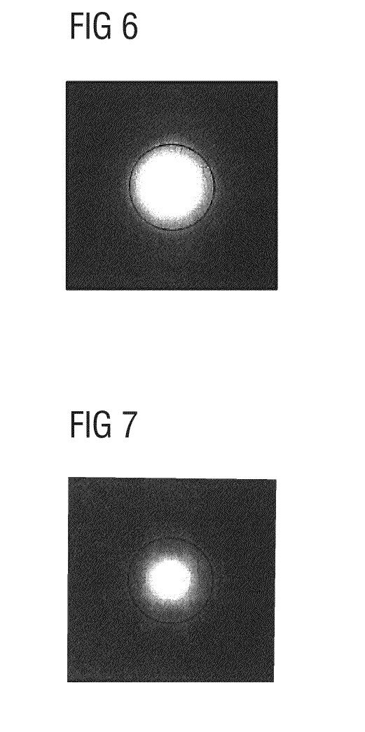

FIG. 6 shows the radiation intensity distribution of a Lambertian emitter in the radiation exit plane. The black circular line marks an angle of radiation of 38°. As is apparent, the circular area within the black circular line is virtually completely illuminated by the Lambertian emitter.

On the other hand, with a lighting device according to the invention the angle of radiation may be limited such that, as shown in FIG. 7, only an inner part of the circular area defined by the black circular line is illuminated. In this inner part the radiant intensity is distributed homogeneously.

The invention is not restricted by the description given with reference to the exemplary embodiments. Rather, the invention encompasses any novel feature and any combination of features, including, in particular, any combination of features in the claims, even if this feature or this combination is not itself explicitly indicated in the claims or exemplary embodiments.

1. A lighting device comprising:
a chip housing having a recess, which includes a reflective internal surface,
at least one radiation-emitting semiconductor chip with a chip surface, the semiconductor chip arranged in the recess, and
a chip-remote angular filter element integrated into the chip housing and arranged downstream of the semiconductor chip in a preferred direction,
wherein the reflective internal surface is least ten times as large as the chip surface.

2. The lighting device according to claim 1, wherein the reflective internal surface is at least one hundred times larger than the chip surface.

3. The lighting device according to claim 1, wherein the reflective internal surface has a reflectivity of 90% or greater.

4. The lighting device according to claim 1, wherein radiation emitted by the semiconductor chip impinges on the angular filter element and is more strongly reflected within a first incidence angle range than within a second incidence angle range and the first incidence angle range has smaller angles of incidence than the second incidence angle range.

5. The lighting device according to claim 1, wherein radiation emitted by the semiconductor chip impinges on the angular filter element and is more strongly reflected within a second incidence angle range than within a first incidence angle range and the first incidence angle range has smaller angles of incidence than the second incidence angle range.

6. The lighting device according to claim 1, wherein an angle of radiation of radiation emitted by the lighting device is reduced by means of the angular filter element.

7. The lighting device according to claim 1, wherein the reflective internal surface comprises at least one side surface.

8. The lighting device according to claim 7, wherein the side surface is concavely curved.

9. The lighting device according to claim 7, wherein the reflective internal surface comprises a planar bottom surface and a plurality of planar side surfaces, which extend at an angle to the bottom surface.

10. The lighting device according to claim 1, wherein the angular filter element forms a cover for the chip housing.

11. The lighting device according to claim 1, wherein the angular filter element comprises structure elements, which are of conical, pyramidal or prismatic construction or resemble inverse CPCs.

12. The lighting device according to claim 11, wherein the structure elements taper in the preferred direction.

13. The lighting device according to claim 1, wherein the angular filter element comprises a dielectric filter.

14. The lighting device according to claim 1, wherein the recess is partially filled with a filling composition.

15. The lighting device according to claim 14, wherein an air gap is present between the filling composition and the angular filter element.

16. The lighting device according to claim 3, wherein the reflective internal surface has a reflectivity of 95% or greater.

17. The lighting device according to claim 16, wherein the reflective internal surface has a reflectivity of 98% or greater.
